(19) United States
(12) Patent Application Publication
(10) Pub. No.: US 2025/0125588 A1
(43) Pub. Date: Apr. 17, 2025

(54) Optical Device

(71) Applicant: Nippon Telegraph and Telephone Corporation, Tokyo (JP)

(72) Inventors: Yoshiho Maeda, Musashino-shi, Tokyo (JP); Koji Takeda, Musashino-shi, Tokyo (JP); Takuro Fujii, Musashino-shi, Tokyo (JP); Toru Segawa, Musashino-shi, Tokyo (JP); Shinji Matsuo, Musashino-shi, Tokyo (JP)

(21) Appl. No.: 18/721,598

(22) PCT Filed: Dec. 20, 2021
(86) PCT No.: PCT/JP2021/047029

§ 371 Date: Jun. 18, 2024

(51) Int. Cl. H01S 5/323; H01S 5/026

(52) U.S. Cl. CPC H01S 5/323; H01S 5/0264

(57) ABSTRACT

The optical device includes a semiconductor layer formed on a cladding layer and composed of a III-V compound semiconductor, and a light-receiving element for monitoring a semiconductor laser formed on the semiconductor layer and oscillation light of the semiconductor laser. A first p-contact layer and a first n-contact layer of the semiconductor laser, a second p-contact layer and a second n-contact layer, and a light absorption layer of the light-receiving element are composed of the same III-V compound semiconductor (InGaAsP).

### TECHNICAL FIELD

The present invention relates to an optical device provided with a light-emitting element and a light-receiving element.

### BACKGROUND ART

Due to the explosive growth in the amount of network traffic associated with the spread of the Internet, optical fiber transmission continues to increase in speed and capacity. A waveguide-type semiconductor laser is used as an optical device such as an optical transceiver used in optical communication, and has continued to develop as a light source device supporting optical fiber communication. In this type of optical device, a waveguide-type light-receiving element for monitoring output light of the semiconductor laser is integrated. In such light-receiving element for monitoring, it is important to form an absorption layer from a compound semiconductor having a high absorption coefficient in a communication wavelength band.

On the other hand, since the light-receiving element is integrated with the light-emitting element, it is preferable for manufacturing purposes to use the compound semiconductor that constitutes the light-emitting element as the core material in an optical waveguide structure having an absorption layer as the core. However, the compound semiconductor constituting the light-emitting element naturally has a high transmittance in the communication wavelength band, and is not suitable for the light-receiving element. The compound semiconductor used for the active layer of the semiconductor laser has a lower absorption coefficient in the C band and the O band compared with the compound semiconductor used for the light absorption layer of the light-receiving element, and thus do not provide high photosensitivity.

For this reason, in a portion of the light-receiving element, a layer of the compound semiconductor for constituting the light-emitting element is removed once, and a compound semiconductor layer having a high absorption coefficient in a communication wavelength band is recreated. Further, the integration of the light-emitting element and the light-receiving element is realized by so-called hybrid integration.

### CITATION LIST

### Non Patent Literature

[NPL 1] Y. Baumgartner et al., “High-speed CMOS-compatible III-V on Si membrane photodetectors,” Optics Express, vol. 29, No. 1, pp. 509-516, 2021.

[NPL 2] Z. Gu et al., “On-chip membrane-based GaInAs/InP waveguide-type p-i-n photodiode fabricated on silicon substrate,” Applied Optics, vol. 56, No. 28, pp. 7841-7848, 2017.

### SUMMARY OF INVENTION

### Technical Problem

However, the conventional manufacturing method described above has a problem that the integration of the light-emitting element and the light-receiving element increases the cost.

The present invention has been made to solve the above problems, and an object of the present invention is to enable integration of a light-emitting element and a light-receiving element without increasing cost.

### Solution to Problem

An optical device according to the present invention includes: a semiconductor layer formed on a cladding layer and composed of a III-V compound semiconductor; and a waveguide-type light-receiving element for monitoring a waveguide-type semiconductor laser formed on the semiconductor layer and oscillation light of the semiconductor laser, wherein the semiconductor laser includes: a core-shaped active layer formed by being embedded in the semiconductor layer and extending in a predetermined direction; a p-type first p-semiconductor region and an n-type first n-semiconductor region which are formed at positions sandwiching an active layer of the semiconductor layer; a first p-electrode formed on the first p-semiconductor region; a first n-electrode formed on the first n-semiconductor region; a first p-contact layer formed between the first p-semiconductor region and the first p-electrode; and a first n-contact layer formed between the first n-semiconductor region and the first n-electrode, the light-receiving element includes: a non-doped i-semiconductor region formed in the semiconductor layer and extending in a predetermined direction; a p-type second p-semiconductor region and an n-type second n-semiconductor region that are formed at positions sandwiching an i-semiconductor region of the semiconductor layer; a second p-electrode formed on the second p-semiconductor region; a second n-electrode formed on the second n-semiconductor region; a second p-contact layer formed between the second p-semiconductor region and the second p-electrode; a second n-contact layer formed between the second n-semiconductor region and the second n-electrode; and a light absorption layer formed on the i-semiconductor region, the first p-contact layer, the first n-contact layer, the second p-contact layer, the second n-contact layer, and the light absorption layer being composed of the same III-V compound semiconductor.

### Advantageous Effects of Invention

As described above, according to the present invention, since the first p-contact layer and the first n-contact layer of the semiconductor laser, the second p-contact layer and the second n-contact layer, and the light absorption layer of the light-receiving element are composed of the same III-V compound semiconductor, the light-emitting element and the light-receiving element can be integrated without increasing cost.

### BRIEF DESCRIPTION OF DRAWINGS

FIG. 1A is a plan view showing a configuration of an optical device according to Embodiment 1 of the present invention.

FIG. 1B is a cross-sectional view showing a partial configuration of the optical device according to Embodiment 1 of the present invention.

FIG. 1C is a cross-sectional view showing a partial configuration of the optical device according to Embodiment 1 of the present invention.

FIG. 1D is a distribution diagram showing a distribution of the amount of light in a light-receiving element 152 of the optical device according to Embodiment 1 of the present invention.

FIG. 2A is a cross-sectional view showing a partial configuration device according to Embodiment 2 of the present invention.

FIG. 2B is a distribution diagram showing a distribution of the amount of light in a light-receiving element 152a of the optical device according to Embodiment 2 of the present invention.

FIG. 3A is a cross-sectional view showing a partial configuration of an optical device according to Embodiment 3 of the present invention.

FIG. 3B is a distribution diagram showing a distribution of the amount of light in a light-receiving element 152b of the optical device according to Embodiment 3 of the present invention.

FIG. 4A is a cross-sectional view showing a partial configuration of an optical device according to Embodiment 4 of the present invention.

FIG. 4B is a distribution diagram showing a distribution of the amount of light in a light-receiving element 152c of the optical device according to Embodiment 4 of the present invention.

FIG. 5A is a cross-sectional view showing a partial configuration of another optical device according to an embodiment of the present invention.

FIG. 5B is a distribution diagram showing a distribution of the amount of light in a light-receiving element 152d of another optical device according to an embodiment of the present invention.

FIG. 6A is a cross-sectional view showing a partial configuration of another optical device according to an embodiment of the present invention.

FIG. 6B is a distribution diagram showing a distribution of the amount of light in a light-receiving element 152e of another optical device according to an embodiment of the present invention.

### DESCRIPTION OF EMBODIMENTS

Hereinafter, optical devices according to embodiments of the present invention will be described.

### Embodiment 1

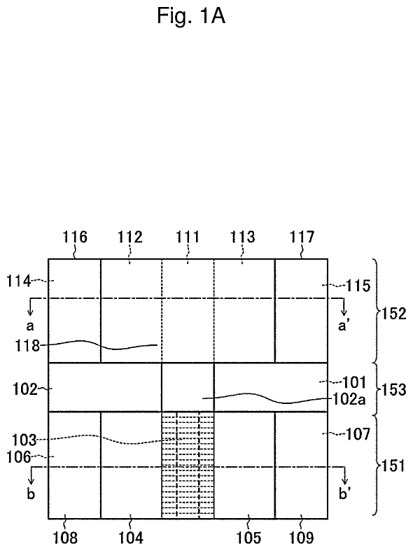

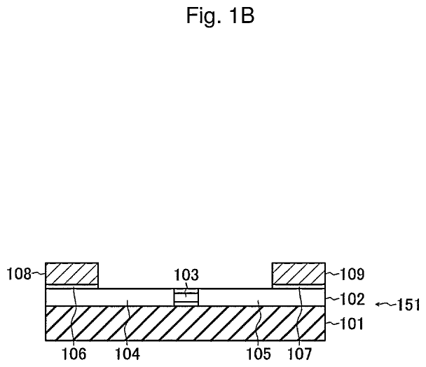

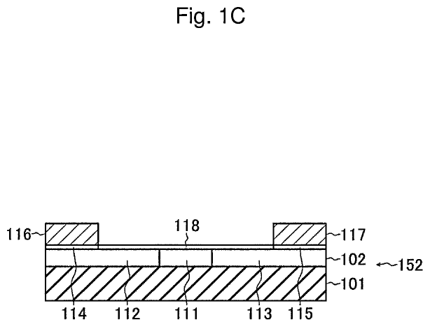

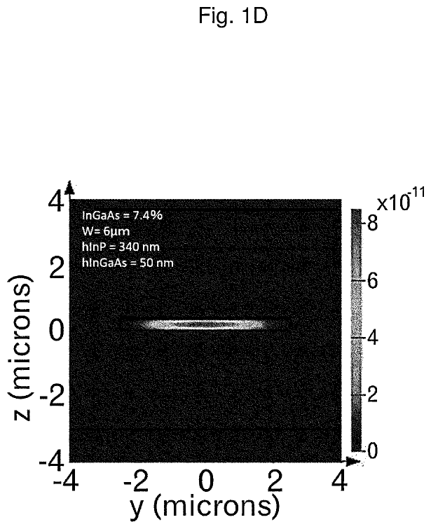

Hereinafter, an optical device according to Embodiment 1 of the present invention will be described with reference to FIGS. 1A, 1B, 1C, and 1D. Note that FIG. 1B shows a cross section taken along a line aa′ of FIG. 1A. Note that FIG. 1C shows a cross section taken along a line bb′ of FIG. 1A.

The optical device is provided with a semiconductor layer 102 made of a III-V compound semiconductor formed on a cladding layer 101, a semiconductor laser 151 formed on the semiconductor layer 102, and a light-receiving element 152 for monitoring oscillation light of the semiconductor laser 151. The semiconductor laser 151 and the light-receiving element 152 are each of a waveguide-type. The semiconductor laser 151 and the light-receiving element 152 are optically connected by a connection optical waveguide 153.

The semiconductor laser 151 is, for example, a well-known lateral current injection type semiconductor laser, and includes a core-shaped active layer 103 embedded in the semiconductor layer 102 made of III-V compound semiconductor, such as InP. The active layer 103 can be composed of, for example, InGaAs. Further, the active layer 103 can have a multi-quantum well structure.

A p-type first p-semiconductor region 104 and an n-type first n-semiconductor region 105 formed so as to sandwich the active layer 103 in a direction perpendicular to the waveguide direction are provided in an optical waveguide by the active layer 103. In this example, the first p-semiconductor region 104 and the first n-semiconductor region 105 are arranged so as to sandwich the active layer 103 in a direction parallel to the plane of the cladding layer 101 (lateral current injection type).

The first p-semiconductor region 104 is composed of a III-V compound semiconductor (InP) doped with a p-type impurity, and the first n-semiconductor region 105 is composed of a III-V compound semiconductor (InP) doped with an n-type impurity. These are formed by doping the semiconductor layer 102 with corresponding impurities. The region of the semiconductor layer 102 in which the active layer 103 is buried is non-doped.

A first p-electrode 108 and a first n-electrode 109 are ohmic-connected to the first p-semiconductor region 104 and the first n-semiconductor region 105 via a first p-contact layer 106 and a first n-contact layer 107. The first p-contact layer 106 and the first n-contact layer 107 are composed of a III-V compound semiconductor doped with a corresponding impurity at a high concentration. The first p-contact layer 106 and the first n-contact layer 107 are composed of, for example, InGaAs. The semiconductor laser 151 thus constructed is a semiconductor laser having the diffraction grating formed on the active layer 103 as a distributed Bragg reflection structure.

Laser oscillation is obtained by injecting a current into the active layer 103 of the semiconductor laser 151 constituting this semiconductor laser, via the first p-electrode 108 and the first n-electrode 109. The laser beam generated by the laser oscillation is output to the connection optical waveguide 153, and guided and received by the light-receiving element 152. The connection optical waveguide 153 is composed of a connection core 102a formed on the cladding layer 101. The connection core 102a is formed by patterning the semiconductor layer 102 between the semiconductor laser 151 and the light-receiving element 152.

The light-receiving element 152 is provided with a non-doped i-semiconductor region 111 formed in the semiconductor layer 102 and extending in a predetermined direction, and a p-type second p-semiconductor region 112 and an n-type second n-semiconductor region 113 formed at positions sandwiching the i-semiconductor region 111 of the semiconductor layer 102. The second p-semiconductor region 112 is composed of a III-V compound semiconductor (InP) doped with a p-type impurity, and the second n-semiconductor region 113 is composed of a III-V compound semiconductor (InP) doped with an n-type impurity. These are formed by doping the semiconductor layer 102 with corresponding impurities.

A second p-electrode 116 and a second n-electrode 117 are ohmic-connected to the second p-semiconductor region 112 and the second n-semiconductor region 113 via a second p-contact layer 114 and a second n-contact layer 115. The second p-contact layer 114 and the second n-contact layer 115 are composed of a III-V compound semiconductor doped with a corresponding impurity at a high concentration. The second p-contact layer 114 and the second n-contact layer 115 are composed of, for example, InGaAs.

Further, the light-receiving element 152 includes a light absorption layer 118 formed on the i-semiconductor region 111. The light absorption layer 118 is composed of, for example, InGaAsP. In this example, the light absorption layer 118 is formed integrally with the second p-contact layer 114 and the second n-contact layer 115. For example, the second p-contact layer 114, the second n-contact layer 115, and the light absorption layer 118 can be formed by doping corresponding impurities into each of regions sandwiching the light absorption layer 118 of the same InGaAsP layer. As shown in the distribution (simulation) of the amount of light in the light-receiving element 152 in FIG. 1D, it can be seen that light is absorbed in the light absorption layer 118.

In the light-receiving element 152, a lateral pin junction is formed by the i-semiconductor region 111, the second p-semiconductor region 112, the and n-type second n-semiconductor region 113 sandwiching the i-semiconductor region 111, and by applying a reverse bias by the second p-electrode 116 and the second n-electrode 117, the light-receiving element 152 operates as a photodiode.

As described above, in the optical device according to Embodiment 1, the first p-contact layer 106, the first n-contact layer 107, the second p-contact layer 114, the second n-contact layer 115, and the light absorption layer 118 are composed of the same III-V compound semiconductor (for example, InGaAsP or InGaAs).

According to Embodiment 1, the semiconductor laser 151 and the light-receiving element 152 have the same layer structure except for the active layer 103 and the diffraction grating. For example, the semiconductor laser 151 and the light-receiving element 152 share the semiconductor layer 102 made of InP. Furthermore, the first p-contact layer 106, the first n-contact layer 107, the second p-contact layer 114, the second n-contact layer 115, and the light absorption layer 118 are formed from layers of the same III-V compound semiconductor (InGaAsP or InGaAs) formed tangentially over semiconductor layer 102.

As a result, according to Embodiment 1, the semiconductor laser 151 and the light-receiving element 152 can be integrated easily at low cost without using additional steps such as crystal regrowth.

For example, the active layer 103 and the semiconductor layer 102 are formed on the cladding layer 101 by burying regrowth, and a diffraction grating is formed on the active layer 103, and thereafter the connection core 102a is formed by a known photolithography technique and an etching technique. Then, the first p-semiconductor region 104 and the second p-semiconductor region 112 are simultaneously formed by selective doping, and the first n-semiconductor region 105 and the second n-semiconductor region 113 are simultaneously formed by selective doping. At the same time, the non-doped i-semiconductor region 111 is formed.

Then, a layer of the III-V compound semiconductor (InGaAsP or InGaAs) for forming each contact layer is formed on the semiconductor layer 102 where each region is formed. Next, the p-type contact layers are simultaneously formed by selective doping, and the n-type contact layers are simultaneously formed. At the same time, the light absorption layer 118 is formed. Thereafter, a predetermined contact layer is separated by known photolithography and etching techniques.

As described above, each layer constituting the semiconductor laser 151 and each layer constituting the light-receiving element 152 can be formed simultaneously except for the formation of the active layer and the diffraction grating.

### Embodiment 2

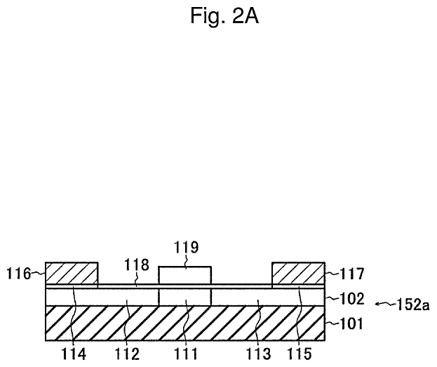

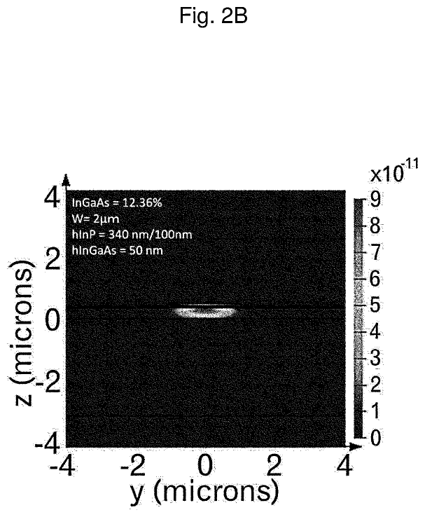

Next, an optical device according to Embodiment 2 of the present invention will be described with reference to FIGS. 2A and 2B. The optical device according to Embodiment 2 includes the semiconductor layer 102 made of a III-V compound semiconductor and formed on the cladding layer 101, a semiconductor laser (not shown) formed on the semiconductor layer 102, and a light-receiving element 152a for monitoring the oscillation light of the semiconductor laser, as in Embodiment 1 described above.

In Embodiment 2, except for the light-receiving element 152a, the rest is the same as in Embodiment 1 described above, and the explanation is omitted accordingly.

The light-receiving element 152a according to Embodiment 2 includes an i-semiconductor region 111 formed in the semiconductor layer 102, the second p-semiconductor region 112 and the second n-semiconductor region 113 formed at positions sandwiching the i-semiconductor region 111 of the semiconductor layer 102, the second p-contact layer 114, the second n-contact layer 115, the second p-electrode 116, and the second n-electrode 117. The configurations of these constituent elements are same as those described in Embodiment 1.

In Embodiment 2, a core layer 119 extending in the same direction as the i-semiconductor region 111 is formed on the i-semiconductor region 111 via the light absorption layer 118. The core layer 119 can be composed of the same III-V compound semiconductor (InP) as that of the semiconductor layer 102.

In Embodiment 2 provided with the core layer 119, since it functions as a rib-type waveguide, it is possible to set a propagation mode, in which light is more strongly confined, in the portion where the core layer 119 is formed. As a result, as shown in the distribution of the amount of light in the light-receiving element 152a of FIG. 2B, the amount of light confined in the light absorption layer 118 at the portion where the core layer 119 is formed can be increased as compared with Embodiment 1.

### Embodiment 3

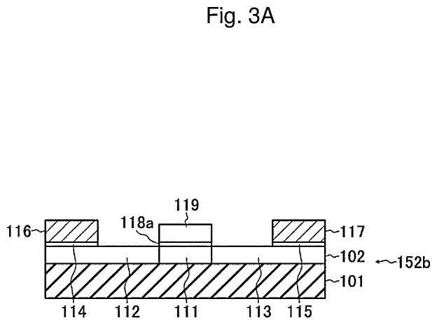

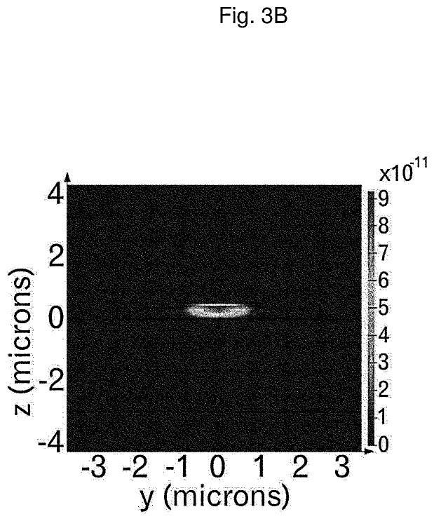

Next, an optical device according to Embodiment 3 of the present invention will be described with reference to FIGS. 3A and 3B. The optical device according to Embodiment 3 includes the semiconductor layer 102 made of a III-V compound semiconductor and formed on the cladding layer 101, a semiconductor laser (not shown) formed on the semiconductor layer 102, and a light-receiving element 152b for monitoring the oscillation light of the semiconductor laser, as in Embodiment 2 described above.

In Embodiment 3, except for the light-receiving element 152b, the rest is the same as in Embodiment 2 described above, and the explanation is omitted accordingly.

In Embodiment 3 as well, as in Embodiment 2, the core layer 119 extending in the same direction as the i-semiconductor region 111 is formed on the i-semiconductor region 111 via the light absorption layer 118. Further, in Embodiment 3, a light absorption layer 118a is formed separately from the second p-semiconductor region 112 and the second n-semiconductor region 113. The light absorption layer 118a is formed in a region immediately below the core layer 119.

In Embodiment 3 provided with the core layer 119 and the light absorption layer 118a separated from each other, since it functions as a rib-type waveguide, it is possible to set a propagation mode, in which light is more strongly confined, in the portion where the core layer 119 is formed. As a result, as shown in the distribution of the amount of light in the light-receiving element 152b of FIG. 3B, the amount of light confined in the light absorption layer 118a at the portion where the core layer 119 is formed can be increased as compared with Embodiment 1.

### Embodiment 4

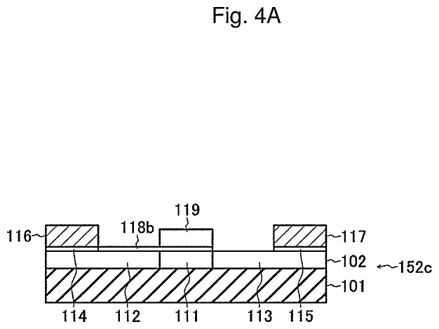

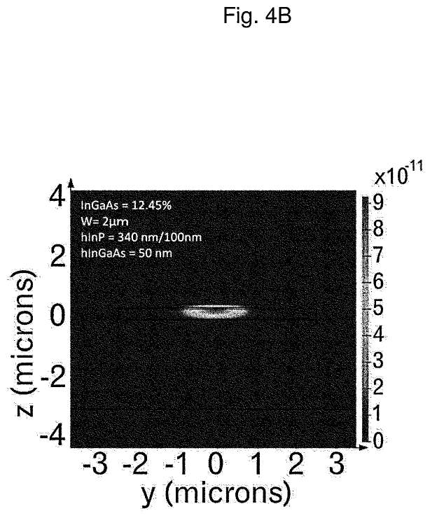

Next, an optical device according to Embodiment 4 of the present invention will be described with reference to FIGS. 4A and 4B. The optical device according to Embodiment 4 includes the semiconductor layer 102 made of a III-V compound semiconductor and formed on the cladding layer 101, a semiconductor laser (not shown) formed on the semiconductor layer 102, and a light-receiving element 152c for monitoring the oscillation light of the semiconductor laser, as in Embodiment 2 described above.

In Embodiment 4, except for the light-receiving element 152c, the rest is the same as in Embodiment 2 described above, and the explanation is omitted accordingly.

In Embodiment 4 as well, as in Embodiment 2, the core layer 119 extending in the same direction as the i-semiconductor region 111 is formed on the i-semiconductor region 111 via a light absorption layer 118b. Further, in Embodiment 4, the light absorption layer 118b is formed integrally with the second p-contact layer 114, and separated from the second n-semiconductor region 113. In Embodiment 4, the second n-semiconductor region 113 is formed only in a region immediately below the second n-electrode 117.

In Embodiment 4, since the second n-semiconductor region 113 is separated from the light absorption layer 118b and is formed away from the core layer 119 and the i-semiconductor region 111, and since the formation of holes in the second n-semiconductor region 113 due to light absorption does not occur, high-speed operation can be expected. Also in Embodiment 4 as well, as shown in the distribution of the amount of light in the light-receiving element 152c of FIG. 4B, a higher amount of light is confined in the light absorption layer 118a at the portion where the core layer 119 is formed.

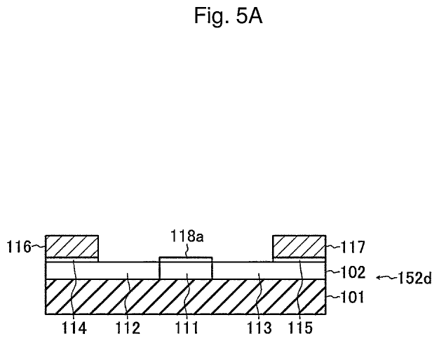

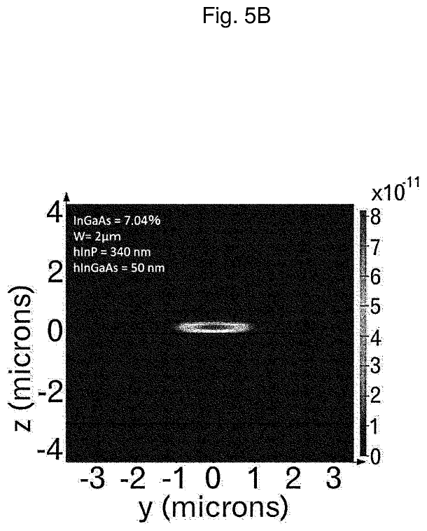

Incidentally, as shown in FIG. 5A, a light-receiving element 152d can be configured in which the light absorption layer 118a is formed separately from the second p-semiconductor region 112 and the second n-semiconductor region 113 and a core layer is not formed. Also in this configuration, since the separated light absorption layer 118a functions as a rib-type waveguide, a propagation mode in which light is confined in the light absorption layer 118a can be set (FIG. 5B).

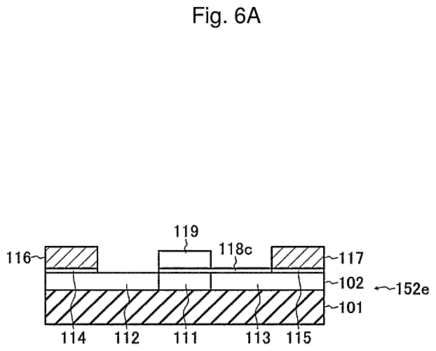

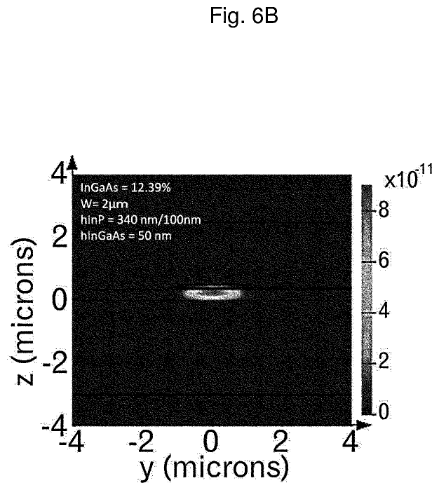

Further, as shown in FIG. 6A, a light absorption layer 118c is formed integrally with the second n-contact layer 115, and a light-receiving element 152e separated from the second p-semiconductor region 114 can be formed. The second p-semiconductor region 114 is formed only in a region immediately below the second p-electrode 116. Even in this configuration, a propagation mode in which light is confined in the light absorption layer 118c sandwiched between the core layer 119 and the i-semiconductor region 111 can be obtained (FIG. 6B).

As described above, according to the present invention, the first p-contact layer and the first n-contact layer of the semiconductor laser, the second p-contact layer and the second n-contact layer, and the light absorption layer of the light-receiving element are composed of the same III-V compound semiconductor, so that the light-emitting element and the light-receiving element can be integrated without increasing cost.

Note that it is clear that the present invention is not limited to the embodiments described above, and that many variations and combinations can be implemented by those having ordinary knowledge in the art within the technical concept of the present invention.

### Reference Signs List

101 Cladding layer
102 Semiconductor layer
102a Connection core
103 Active layer
104 First p-semiconductor region
105 First n-semiconductor region
106 First p-contact layer 106
107 First n-contact layer
108 First p-electrode
109 First n-electrode
111 i-semiconductor region
112 Second p-semiconductor region
113 Second n-semiconductor region
114 Second p-contact layer
115 Second n-contact layer
116 Second p-electrode
117 Second n-electrode
118 Light absorption layer
151 Semiconductor laser
152 Light-receiving element
153 Connection optical waveguide

1. An optical device, comprising:
a semiconductor layer formed on a cladding layer and composed of a III-V compound semiconductor; and
a waveguide-type light-receiving element for monitoring a waveguide-type semiconductor laser formed on the semiconductor layer and oscillation light of the semiconductor laser,
wherein the semiconductor laser includes:
a core-shaped active layer formed by being embedded in the semiconductor layer and extending in a predetermined direction;
a p-type first p-semiconductor region and an n-type first n-semiconductor region which are formed at positions sandwiching an active layer of the semiconductor layer;
a first p-electrode formed on the first p-semiconductor region;
a first n-electrode formed on the first n-semiconductor region;
a first p-contact layer formed between the first p-semiconductor region and the first p-electrode; and
a first n-contact layer formed between the first n-semiconductor region and the first n-electrode,
the light-receiving element includes:
a non-doped i-semiconductor region formed in the semiconductor layer and extending in a predetermined direction;
a p-type second p-semiconductor region and an n-type second n-semiconductor region that are formed at positions sandwiching an i-semiconductor region of the semiconductor layer;
a second p-electrode formed on the second p-semiconductor region;
a second n-electrode formed on the second n-semiconductor region;
a second p-contact layer formed between the second p-semiconductor region and the second p-electrode;
a second n-contact layer formed between the second n-semiconductor region and the second n-electrode; and
a light absorption layer formed on the i-semiconductor region,
the first p-contact layer, the first n-contact layer, the second p-contact layer, the second n-contact layer, and the light absorption layer being composed of the same III-V compound semiconductor.

2. The optical device according to claim 1, comprising:
a core layer formed on the i-semiconductor region via the light absorption layer and extending in the same direction as the i-semiconductor region,
wherein the core layer is composed of the same III-V compound semiconductor as the semiconductor layer.

3. The optical device according to claim 1,
wherein the light absorption layer is formed integrally with the second p-contact layer and the second n-contact layer.

4. The optical device according to claim 1,
wherein the light absorption layer is formed integrally with the second p-contact layer.

5. The optical device according to claim 1,
wherein the semiconductor layer is composed of InP, and
the first p-contact layer, the first n-contact layer, the second p-contact layer, the second n-contact layer, and the light absorption layer are composed of InGaAsP or InGaAs.

6. The optical device according to claim 2,
wherein the light absorption layer is formed integrally with the second p-contact layer and the second n-contact layer.

7. The optical device according to claim 2,
wherein the light absorption layer is formed integrally with the second p-contact layer.

8. The optical device according to claim 2,
wherein the semiconductor layer is composed of InP, and
the first p-contact layer, the first n-contact layer, the second p-contact layer, the second n-contact layer, and the light absorption layer are composed of InGaAsP or InGaAs.

9. The optical device according to claim 3,
wherein the semiconductor layer is composed of InP, and
the first p-contact layer, the first n-contact layer, the second p-contact layer, the second n-contact layer, and the light absorption layer are composed of InGaAsP or InGaAs.

10. The optical device according to claim 4,
wherein the semiconductor layer is composed of InP, and
the first p-contact layer, the first n-contact layer, the second p-contact layer, the second n-contact layer, and the light absorption layer are composed of InGaAsP or InGaAs.
